(19) United States
(12) Patent Application Publication
(10) Pub. No.: US 2010/0313930 A1
(43) Pub. Date: Dec. 16, 2010

(54) SOLAR BATTERY MODULE, AND ELECTRONIC COMPONENT, ELECTRIC COMPONENT AND ELECTRONIC APPARATUS MOUNTING THE SAME

(76) Inventors: Masato Yokobayashi, Osaka-shi (JP); Tomotoshi Satoh, Osaka-shi (JP); Hiroyuki Nakanishi, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/792,204

(22) Filed: Jun. 2, 2010

(30) Foreign Application Priority Data
Jun. 12, 2009 (JP) 2009-141597

(51) Int. Cl. H01L 31/042

(52) U.S. Cl. 136/244

(57) ABSTRACT

All solar battery cells are in a matrix disposition. Each row of the matrix includes at least two cell groups, and each column of the matrix includes at least two cell groups.

This Nonprovisional application claims priority under 35 U.S.C. §119(a) on Patent Application No. 2009-141597 filed in Japan on Jun. 12, 2009, the entire contents of which are hereby incorporated by reference.

### TECHNICAL FIELD

The present invention relates to a solar battery module, and to an electronic component, an electric component and an electronic apparatus mounting the same.

### BACKGROUND ART

In recent years, solar energy has been attracting attention due to its potential in terms of energy conservation and energy generation, and private solar energy generator systems for home use and the like are becoming more and more popular. Further, in addition to large-sized fixated solar energy generator systems, solar battery modules mountable on portable telephones and the like, small-sized portable solar energy generator systems and the like are appearing. Small-sized solar battery modules are very efficient as a means to electrically charge portable telephones or portable apparatuses in case of emergency, especially in regions with long daylight hours.

For example, Patent Literature 1 discloses a solar battery module able to reduce a temperature rise when installed on a building.

### Citation List

Patent Literature 1

Japanese Patent Application Publication, Tokukai, No. 2009-76693 (Publication Date: Apr. 9, 2009)

### SUMMARY OF INVENTION

### Technical Problem

However, general solar battery modules have such a problem that an amount of electric power generated decreases considerably not only when no sunlight is received, but also when only a part of the module is shaded.

FIG. 14 is an explanatory drawing of a disposition of solar battery cells A and B in a general solar battery module 101. (a) to (c) of FIG. 14 are schematic views showing the disposition of the solar battery cells A and B in the general solar battery module 101.

In (a) of FIG. 14, the totality of the solar battery module 101 receives light and the solar battery module 101 generates a maximum amount of electric power. In (b) of FIG. 14, a left-side ½ area α of the solar battery module 101 or a right-side ½ area β of the solar battery module 101 is shaded. In (c) of FIG. 14, an upper ½ area γ of the solar battery module 101 or a lower ½ area δ of the solar battery module 101 is shaded.

A schematic view of an internal circuit of the solar battery module 101 is shown in FIG. 15. In FIG. 15, reference sign A indicates a solar battery cell A, and reference sign B indicates a solar battery cell B. In the internal circuit shown in FIG. 15, two anodes of the solar battery cell A are connected to an extraction electrode 109, and two cathodes of the solar battery cell B are connected to an extraction electrode 110. The two cathodes of the solar battery cell A and the two anodes of the solar battery cell B are connected to one another.

FIG. 16 is a graph showing an electric power outputted in each configuration of the solar battery module 101 illustrated in (a) to (c) of FIG. 14. In FIG. 16, a curve 104 corresponds to an outputted electric power of the solar battery module 101 in the disposition shown in (a) of FIG. 14.

A curve 105 corresponds to an outputted electric power of the solar battery module 101 in the disposition shown in (b) of FIG. 14. As shown by the curve 105, an amount of electric power generated when the left-side ½ area α or the right-side ½ area β is shaded is about ½ of an amount of electric power generated when the left-side ½ area α and the right-side ½ area β are not shaded (curve 104).

A curve 106 corresponds to an outputted electric power of the solar battery module 101 in the disposition shown in (c) of FIG. 14. As shown by the curve 106, an amount of electric power generated when the upper ½ area γ or the lower ½ area δ is shaded is considerably lower than ½ of an amount of electric power generated when the upper ½ area γ and the lower ½ area δ are not shaded (curve 105).

Further, FIG. 17 is a schematic view of a disposition of solar battery cells A and B in another general solar battery module 107. The general solar battery module 107 is configured similarly to the general solar battery module 101 (shown in FIG. 14) having been rotated 90° counterclockwise. With the general solar battery module 107, an amount of electric power generated when the left-side ½ area α or the right-side ½ area β is shaded is considerably lower than ½ of the amount of electric power generated when the left-side ½ area α and the right-side ½ area β are not shaded (curve 105 of FIG. 16). Further, an amount of electric power generated when the upper ½ area γ or the lower ½ area δ is shaded is about ½ of an amount of electric power generated when the upper ½ area γ and the lower ½ area δ are not shaded (curve 105 of FIG. 16).

In this way, such a problem occurs with solar battery modules having a general cell disposition that an amount of generated electric power decreases considerably even when only a part of the solar battery module is shaded.

The present invention is attained in view of the above problems. An object of the present invention is to provide (i) a solar battery module able to achieve a stable energy supply without a considerable decrease in electric power generation efficiency even when partially shaded, and (ii) an electronic component, an electric component and an electronic apparatus mounting the same. Solution to Problem

In order to solve the above problems, a solar battery module in accordance with the present invention includes at least two cell groups each constituted by electrically connecting in parallel at least two solar battery cells, said at least two cell groups being connected in series, all of the solar battery cells being in a matrix disposition, each row of the matrix including at least two cell groups and each column of the matrix including at least two cell groups.

With the above configuration, even in a case where a part of the solar battery module becomes shaded and only one row or one column fully receives sunlight, at least two cell groups are included in the row or the column fully receiving sunlight. Accordingly, there is not a single cell group among the plurality of cell groups which does not receive any sunlight. As a result, it is possible to provide a solar battery module able to achieve a stable energy supply without a considerable decrease in electric power generation efficiency even when partially shaded.

In order to solve the above problems, a solar battery module in accordance with the present invention includes (i) at least two solar battery cells and (ii) at least three first cell groups each constituted by electrically connecting in parallel at least two solar battery cells, at least two of said at least three first cell groups being electrically connected in series with each other to constitute a second cell group, the (i) at least two solar battery cells and the second cell group are connected in parallel with each other to constitute a third cell group, one of said at least three first cell groups not constituting the second cell group being electrically connected in series with the third cell group to constitute the solar battery module, all of the solar battery cells being in a matrix disposition, each row of the matrix including the first cell group and the third cell group, and each column of the matrix including the first cell group and the third cell group.

With the above configuration, even in a case where a part of the solar battery module becomes shaded and only one row or one column fully receives sunlight, the first cell group and the third cell group are included in the row or the column fully receiving sunlight. Accordingly, there is not a single cell group which does not receive any sunlight among the first cell group and the third cell group. As a result, it is possible to provide a solar battery module able to achieve a stable energy supply without a considerable decrease in electric power generation efficiency even when partially shaded.

In order to solve the above problems, a solar battery module in accordance with the present invention includes (i) at least three solar battery cells and (ii) at least one first cell group constituted by electrically connecting in series at least two solar battery cells, at least one of said (i) at least three solar battery cells and said at least one first cell group being electrically connected in parallel with each other to constitute a second cell group, at least two of said at least three solar battery cells other than the solar battery cells constituting the second cell group being electrically connected in parallel with each other to constitute a third cell group, and the third cell group and the second cell group being electrically connected in series with each other to constitute the solar battery module, all of the solar battery cells being in a matrix disposition, each row of the matrix including the second cell group and the third cell group, and each column of the matrix including the second cell group and the third cell group.

With the above configuration, even in a case where a part of the solar battery module becomes shaded and only one row or one column fully receives sunlight, the second cell group and the third cell group are included in the row or the column fully receiving sunlight. Accordingly, there is not a single cell group which does not receive any sunlight among the second cell group and the third cell group. As a result, it is possible to provide a solar battery module able to achieve a stable energy supply without a considerable decrease in electric power generation efficiency even when partially shaded.

In order to solve the above problems, a solar battery module includes at least four first cell groups each constituted by electrically connecting in series at least two solar battery cells, every at least two of said at least four first cell groups being electrically connected in parallel with each other to constitute at least two second cell groups, said at least two second groups being electrically connected in series with each other to constitute the solar battery module, all of the solar battery cells being in a matrix disposition, each row of the matrix including at least two second cell groups and each column of the matrix including at least two second cell groups.

With the above configuration, even in a case where a part of the solar battery module becomes shaded and only one row or one column fully receives sunlight, at least two of the second cell groups are included in the row or the column fully receiving sunlight. Accordingly, there is not a single second cell group which does not receive any sunlight. As a result, it is possible to provide a solar battery module able to achieve a stable energy supply without a considerable decrease in electric power generation efficiency even when partially shaded.

### Advantageous Effects of Invention

As above, in a solar battery module in accordance with the present invention, all of the solar battery cells are in a matrix disposition, so that each row of the matrix includes at least two cell groups, and so that each column of the matrix includes at least two cell groups.

Further, as above, a solar battery module in accordance with the present invention includes (i) at least two solar battery cells and (ii) at least three first cell groups each constituted by electrically connecting in parallel at least two solar battery cells, at least two of said at least three first cell groups being electrically connected in series with each other to constitute a second cell group, the (i) at least two solar battery cells and the second cell group are connected in parallel with each other to constitute a third cell group, one of said at least three first cell groups not constituting the second cell group being electrically connected in series with the third cell group to constitute the solar battery module, all of the solar battery cells being in a matrix disposition, each row of the matrix including the first cell group and the third cell group, and each column of the matrix including the first cell group and the third cell group.

In addition, as above, a solar battery module in accordance with the present invention includes (i) at least three solar battery cells and (ii) at least one first cell group constituted by electrically connecting in series at least two solar battery cells, at least one of said at least three solar battery cells and said at least one first cell group being electrically connected in parallel with each other to constitute a second cell group, at least two of said at least three solar battery cells other than the solar battery cells constituting the second cell group being electrically connected in parallel with each other to constitute a third cell group, and the third cell group and the second cell group being electrically connected in series with each other to constitute the solar battery module, all of the solar battery cells being in a matrix disposition, each row of the matrix including the second cell group and the third cell group, and each column of the matrix including the second cell group and the third cell group.

Moreover, as above, a solar battery module includes at least four first cell groups each constituted by electrically connecting in series at least two solar battery cells, every at least two of said at least four first cell groups being electrically connected in parallel with each other to constitute at least two second cell groups, said at least two second groups being electrically connected in series with each other to constitute the solar battery module, all of the solar battery cells being in a matrix disposition, each row of the matrix including at least two second cell groups, and each column of the matrix including at least two second cell groups.

As a consequence, it is possible to provide a solar battery module able to achieve a stable energy supply without a considerable decrease in electric power generation efficiency even when partially shaded, and to provide an electronic component, an electric component and an electronic apparatus mounting the solar battery module.

### BRIEF DESCRIPTION OF DRAWINGS

FIG. 1 is a schematic view of a solar battery module in accordance with an embodiment of the present invention.

FIG. 2 is a schematic view showing the disposition of a solar battery cell in the solar battery module in accordance with an embodiment of the present invention.

FIG. 3 is a schematic view of an internal circuit of the solar battery module in accordance with an embodiment of the present invention.

FIG. 4 illustrates an example of a pattern on a module substrate which corresponds to a disposition of solar battery cells in the solar battery module in accordance with an embodiment of the present invention.

FIG. 5 is a schematic view of an internal circuit of another solar battery module in accordance with an embodiment of the present invention.

FIG. 6 is an explanatory drawing of an internal circuit of yet another solar battery module in accordance with an embodiment of the present invention. (a) and (b) of FIG. 6 are schematic views of an internal circuit of yet another solar battery module in accordance with an embodiment of the present invention.

FIG. 7 is a schematic view of a solar battery module in accordance with another embodiment of the present invention.

FIG. 8 is an explanatory drawing of a disposition of solar battery cells in a general solar battery module. (a) to (c) of FIG. 8 are schematic views of a disposition of the solar battery cells in a general solar battery module.

FIG. 9 is a schematic view of an internal circuit in a general solar battery module.

FIG. 10 is a schematic view of the disposition of solar battery cells in a solar battery module in accordance with another embodiment of the present invention.

FIG. 11 is a schematic view of an internal circuit of a solar battery module in accordance with another embodiment of the present invention.

FIG. 12 illustrates an example of a pattern on a module substrate which corresponds to a disposition of solar battery cells in the solar battery module in accordance with another embodiment of the present invention.

FIG. 13 illustrates a disposition of solar battery cells in a solar battery module in accordance with yet another embodiment of the present invention. (a) to (f) of FIG. 13 are schematic views of the disposition of solar battery cells in a solar battery module in accordance with yet another embodiment of the present invention.

FIG. 14 is an explanatory drawing of a disposition of solar battery cells in a general solar battery module. (a) to (c) of FIG. 14 are schematic views of the disposition of solar battery cells in a general solar battery module.

FIG. 15 is a schematic view of an internal circuit of a general solar battery module.

FIG. 16 is a graph showing an outputted electric power in each of the dispositions of the solar battery modules illustrated in (a) to (c) of FIG. 14.

FIG. 17 is a schematic view of a disposition of solar battery cells in another general solar battery module.

### DESCRIPTION OF EMBODIMENTS

### Embodiment 1

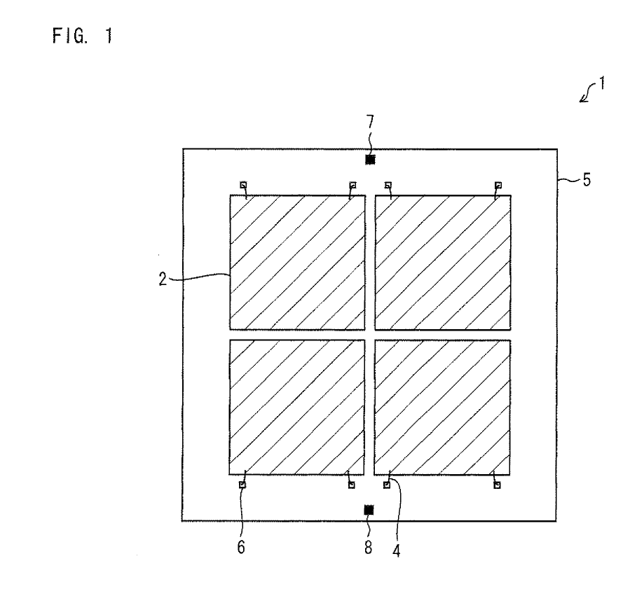

Following is an explanation of one embodiment of the present invention, with reference to FIGS. 1 to 6.

FIG. 1 is a schematic view of a solar battery module (solar battery cell module) 1 in accordance with an embodiment of the present invention. The solar battery module 1 includes four solar battery cells 2, a cell group 3 (cell group) being constituted by connecting in parallel two of the solar battery cells 2. Moreover, two cell groups 3 are connected in series. The solar battery module 1 is denominated 2-parallel, 2-series solar battery module.

In the solar battery module 1, (i) each solar battery cell and (ii) an on-substrate land 6 formed on a module substrate 5 are connected to each other via a bonding wire 4. Further, in the solar battery module 1, extraction electrodes 7 and 8, formed on the module substrate 5, are electrodes used to connect electrically the solar battery module 1 and an electronic component, an electric component or an electronic apparatus on which the solar battery module 1 is mounted or which are supplied with electric power from the solar battery module 1. The extraction electrodes 7 and 8 may also connect electrically the solar battery module 1 and another solar battery module.

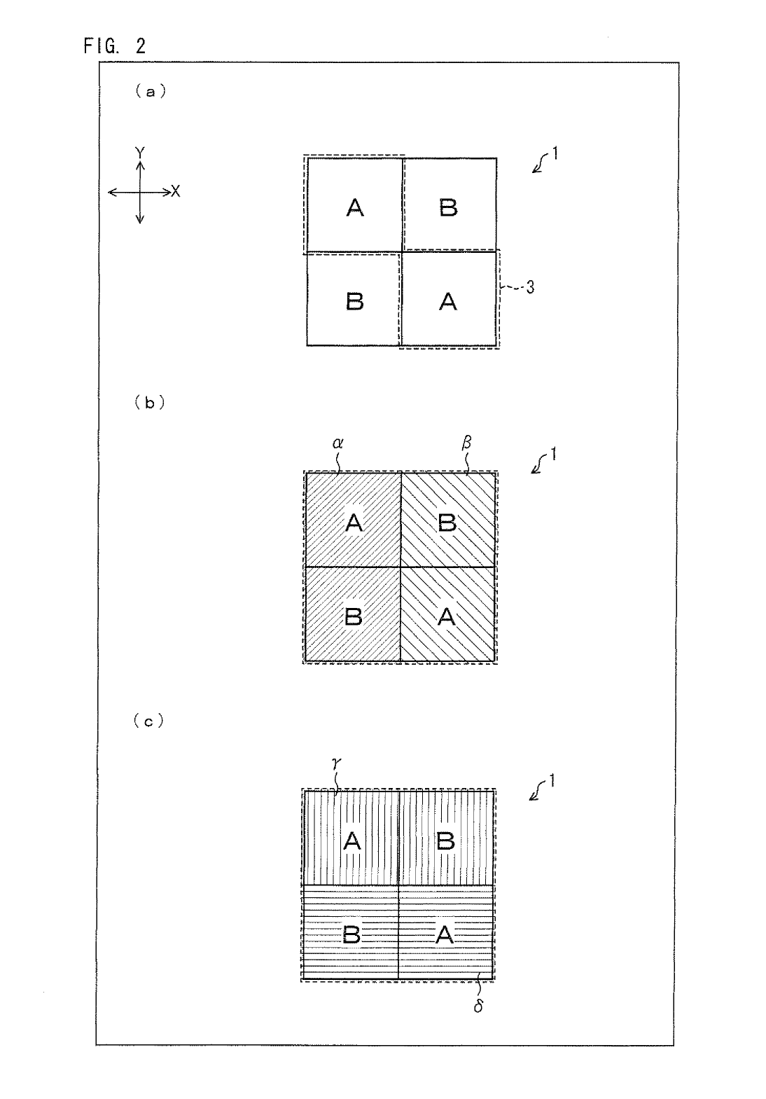

A disposition of the solar battery cells in the solar battery module 1 in accordance with the present embodiment is shown in (a) to (c) of FIG. 2. Reference signs A and B in FIG. 2 indicate each solar battery cell 2. Hereinafter, the solar battery cells 2 corresponding to reference sign A will be referred to as solar battery cells A, and the solar battery cells 2 corresponding to reference sign B will be referred to as solar battery cells B. Two solar battery cells A are electrically connected in parallel to constitute the cell group 3. Similarly, two solar battery cells B are electrically connected in parallel to constitute the cell group 3.

In the solar battery module 1, the solar battery cells A and B are in a matrix disposition, X axis being a row axis and Y axis being a column axis in the solar battery module 1 shown in (a) to (c) of FIG. 2. In this case, in the solar battery module 1, each row of the matrix includes at least two cell groups 3 and each column of the matrix includes at least two cell groups 3. Accordingly, even in a case where a part of the solar battery module becomes shaded and only one row or one column fully receives sunlight, at least two cell groups 3 are included in the row or the column fully receiving sunlight. Accordingly, there is not a single cell group among the plurality of cell groups which does not receive any sunlight. As a result, it is possible to provide a solar battery module able to achieve a stable energy supply without a considerable decrease in electric power generation efficiency even when partially shaded.

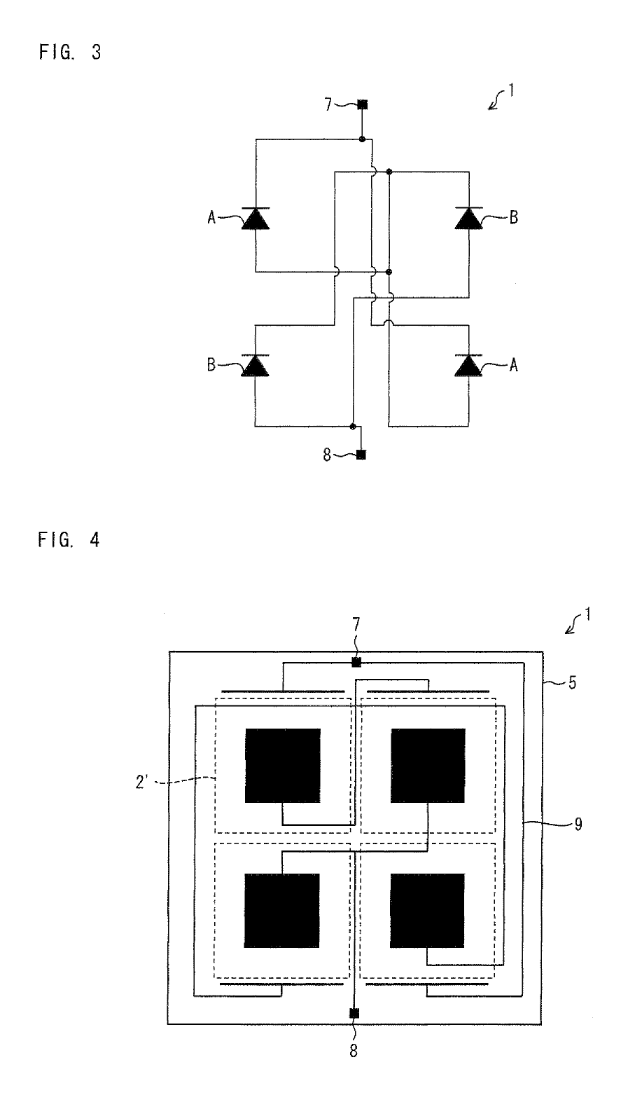

A schematic view of an internal circuit of the solar battery module 1 in accordance with the present embodiment is shown in FIG. 3. In FIG. 3, reference sign A indicates a solar battery cell A, and reference sign B indicates a solar battery cell B. In the internal circuit shown in FIG. 3, two anodes of the solar battery cell A are connected to an extraction electrode 7, and two cathodes of the solar battery cell B are connected to an extraction electrode 8. The two cathodes of the solar battery cell A and the two anodes of the solar battery cell B are connected to one another.

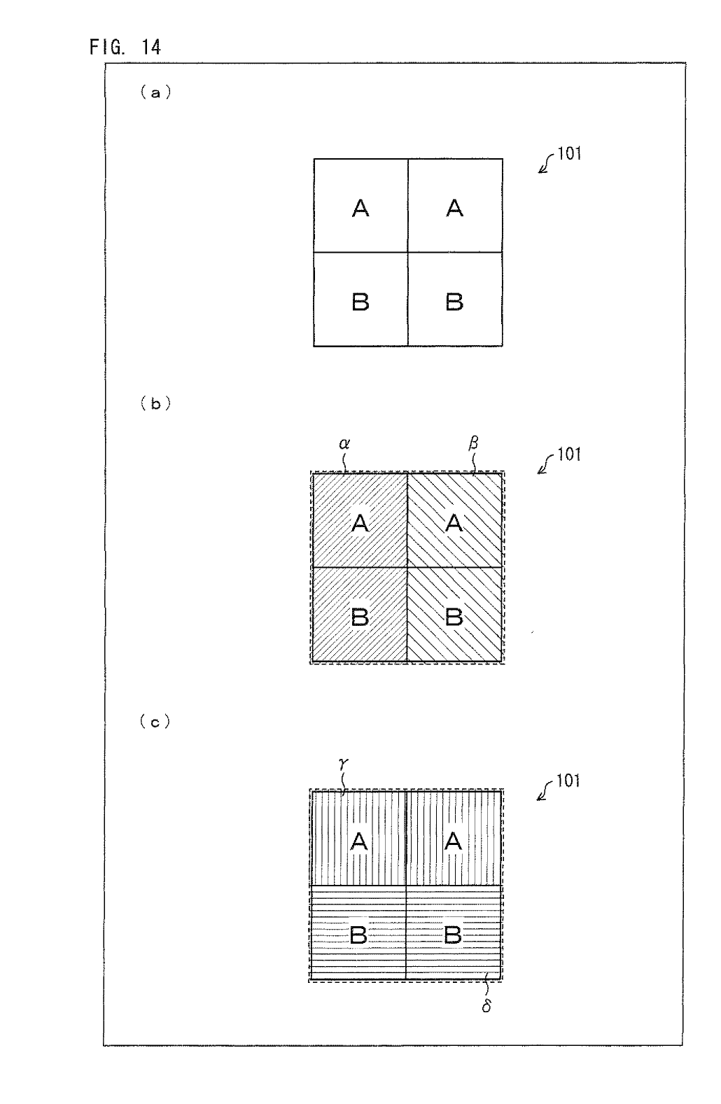

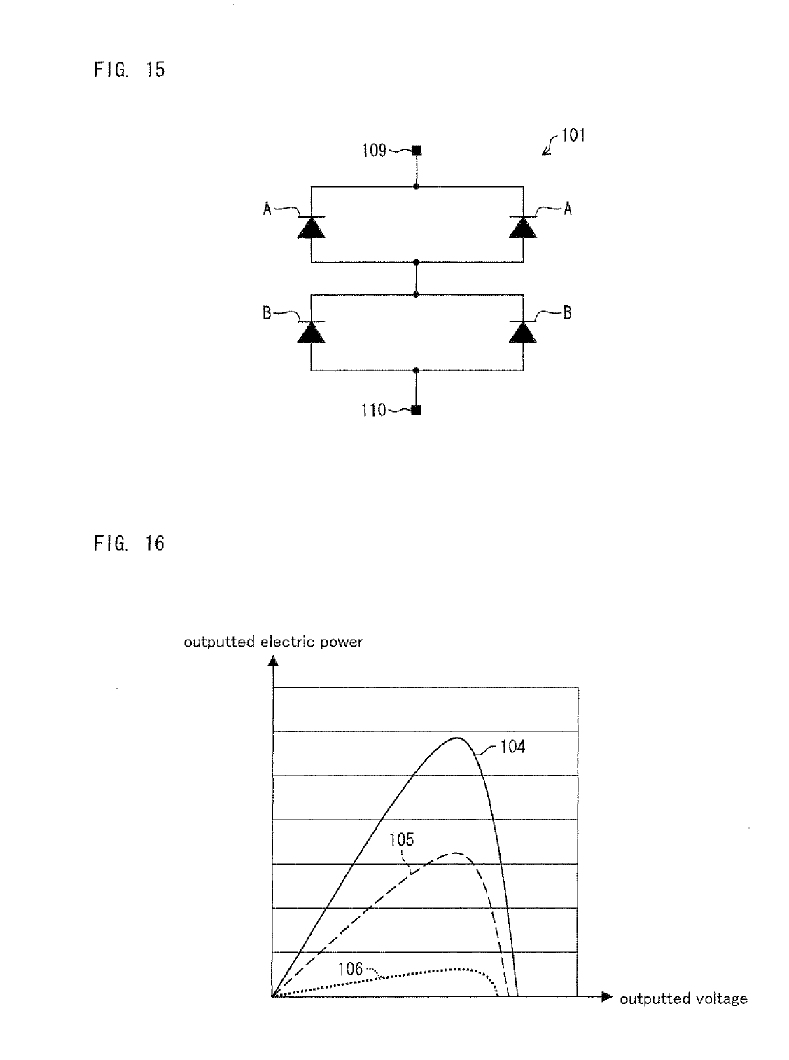

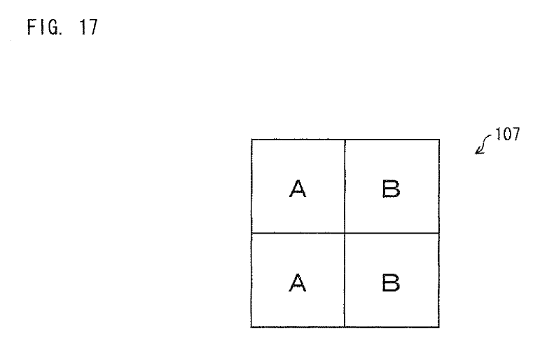

The amount of electric power generated by the conventional solar battery module 101 shown in (a) of FIG. 14 when the totality of the conventional solar battery module 101 receives light is illustrated by the curve 104 in FIG. 16. With the disposition of the solar battery cells in the conventional solar battery module 101 shown in (b) of FIG. 14, an amount of electric power generated when the left-side ½ area α or the right-side ½ area β is shaded is about ½ of an amount of electric power generated when the left-side ½ area α and the right-side ½ area β are not shaded (curve 105 of FIG. 16). In contrast, with the disposition of the solar battery cells in the conventional solar battery module 101 shown in (c) of FIG. 14, an amount of electric power generated when the upper ½ area γ or the lower ½ area δ is shaded is considerably lower than ½ of an amount of electric power generated when the upper ½ area γ and the lower ½ area δ are not shaded (curve 105 of FIG. 16).

In contrast, the amount of electric power generated by the solar battery module 1 in accordance with the present embodiment shown in (a) of FIG. 2, when the totality of the solar battery module 1 receives light, is illustrated by the curve 104 in FIG. 16. With the disposition of the solar battery cells in the solar battery module 1 shown in (b) of FIG. 2, an amount of electric power generated when the left-side ½ area α or the right-side ½ area β is shaded is about ½ of an amount of electric power generated when the left-side ½ area α and the right-side ½ area β are not shaded (curve 105 of FIG. 16). Further, with the disposition of the solar battery cells in the conventional solar battery module 101 shown in (c) of FIG. 2, an amount of electric power generated when the upper ½ area γ or the lower ½ area δ is shaded is about ½ of an amount of electric power generated when the upper ½ area γ and the lower ½ area δ are not shaded (curve 105 of FIG. 16).

In this way, in the solar battery module 1, the amount of electric power generated when the upper ½ area γ or the lower ½ area δ is shaded is about ½ of the amount of electric power generated when the upper ½ area γ and the lower ½ area δ are not shaded (curve 105 of FIG. 16), similarly to the amount of electric power generated when the left-side ½ area α or the right-side ½ area is shaded.

Accordingly, with the solar battery module 1 in accordance with Embodiment 1, there is no such considerable decrease of the amount of generated electric power as in the case of the conventional solar battery module 101, even when a part of the solar battery module 1 is shaded, and it is possible to achieve a stable electric power supply.

FIG. 4 illustrates an example of a pattern 9 on the module substrate 5, the pattern 9 corresponding to the disposition of the solar battery cell 2 in the solar battery module 1 in accordance with the present embodiment. Reference sign 2′ indicates where the solar battery cell 2 is disposed.

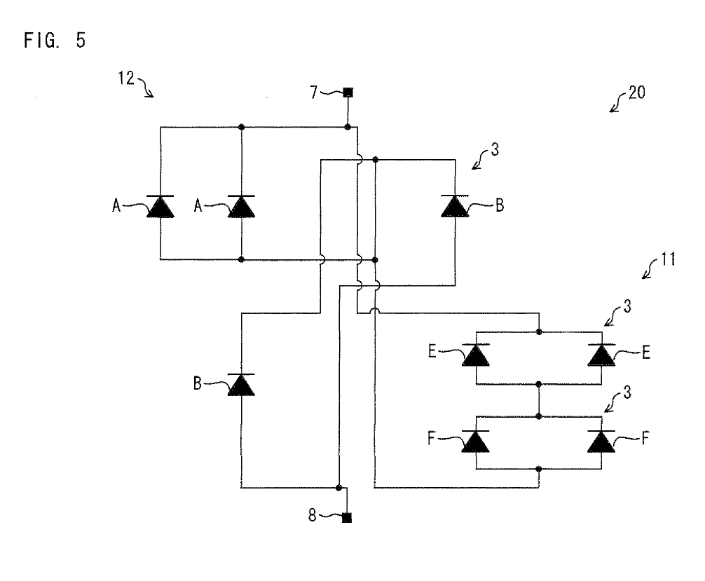

The present invention may be arranged such that the solar battery cells A electrically connected in parallel with each other are electrically connected in parallel with a cell group 11 (second cell group) constituted by electrically connecting two cell groups 3 (first cell group) in series to constitute a solar battery module 20. FIG. 5 is a schematic view of an internal circuit of the solar battery module 20.

In the solar battery module 20, the cell group 11 (second cell group) is constituted by electrically connecting in series (i) a cell group 3 including two solar battery cells E electrically connected in parallel, and (ii) a cell group 3 including two solar battery cells F electrically connected in parallel. Next, a cell group 12 (third cell group) is constituted by electrically connecting in parallel (i) the cell group 11 and (ii) two solar battery cells A. Then, the solar battery module 20 is constituted by electrically connecting in series (i) the cell group 3 including two solar battery cells B electrically connected in parallel and (ii) the cell group 12.

In the solar battery module 20, all the solar battery cells A, B, E, and F are in a matrix disposition. In the matrix, each row includes (i) the cell group 3 including two solar battery cells B electrically connected in parallel and (ii) the cell group 12, and each column includes (i) the cell group 3 including two solar battery cells B electrically connected in parallel and (ii) the cell group 12.

With the above configuration, even in a case where a part of the solar battery module 20 becomes shaded and only one row or one column fully receives sunlight, (i) the cell group 3 including two solar battery cells B electrically connected in parallel and (ii) the cell group 12 are included in the row or the column fully receiving sunlight. Accordingly, there is not a single cell group among cell group 3 and cell group 12 which does not receive any sunlight. As a result, it is possible to provide a solar battery module able to achieve a stable energy supply without a considerable decrease in electric power generation efficiency even when partially shaded.

In the solar battery module 20, it must be noted that, while the cell group 12 includes two solar battery cells A electrically connected in parallel, the cell group 12 may include more than two solar battery cells A electrically connected in parallel.

In the solar battery module 1, each row of the matrix may include all cell groups 3, and each column of the matrix may include all cell groups 3.

Further, in the solar battery module 20, each row of the matrix may include the cell group 3, the cell group 11 and the cell group 12, and each column of the matrix may include the cell group 3, the cell group 11 and the cell group 12.

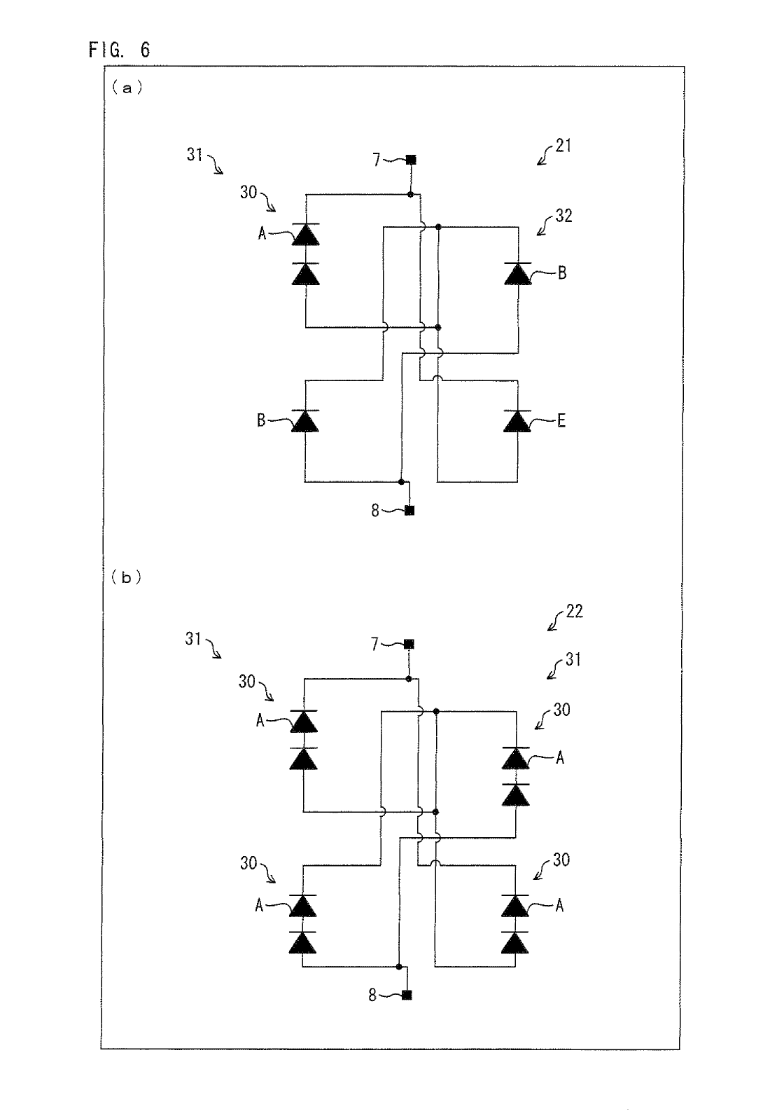

Additionally, the solar battery module may also include a cell group constituted by electrically connecting in series at least two solar battery cells. FIG. 6 is an explanatory drawing of internal circuits of solar battery modules 21 and 22. (a) of FIG. 6 is a schematic view of the internal circuit of the solar battery module 21, and (b) of FIG. 6 is a schematic view of the internal circuit of the solar battery module 22.

In the solar battery module 21, a cell group 30 (first cell group) constituted by electrically connecting two solar cells A in series is connected with a solar battery cell E to constitute a cell group 31. (second cell group). Next, two solar battery cells B are electrically connected in parallel with each other to constitute a cell group 32 (third cell group), and the cell group 32 and the cell group 31 are electrically connected in series with each other to constitute the solar battery module 21.

In the solar battery module 21, all of the solar battery cells A, B, E are in a matrix disposition. In the matrix, each row includes the cell group 31 and the cell group 32, and each column includes the cell group 31 and the cell group 32.

With the above configuration, even in a case where a part of the solar battery module 21 becomes shaded and only one row or one column fully receives sunlight, the cell group 31 and the cell group 32 are included in the row or the column fully receiving sunlight. Accordingly, there is not a single cell group among the cell group 31 and the cell group 32 which does not receive any sunlight. As a result, it is possible to provide a solar battery module able to achieve a stable energy supply without a considerable decrease in electric power generation efficiency even when partially shaded.

In the solar battery module 22, at least four cell groups 30 (first cell group) are each constituted by electrically connecting in series two solar battery cells A, and every at least two of said at least four cell groups 30 are electrically connected in parallel with each other to constitute at least two cell groups 31 (second cell group). Next, said at least two cell groups 31 are electrically connected in series with each other to constitute the solar battery module 22.

In the solar battery module 22, all of the solar battery cells A are in a matrix disposition. In the matrix, each row includes at least two cell groups 31, and each column includes at least two cell groups 31.

With the above configuration, even in a case where a part of the solar battery module 22 becomes shaded and only one row or one column fully receives sunlight, at least two cell groups 31 are included in the row or the column fully receiving sunlight. Accordingly, there is not a single cell group 31 which does not receive any sunlight. As a result, it is possible to provide a solar battery module able to achieve a stable energy supply without a considerable decrease in electric power generation efficiency even when partially shaded.

### Embodiment 2

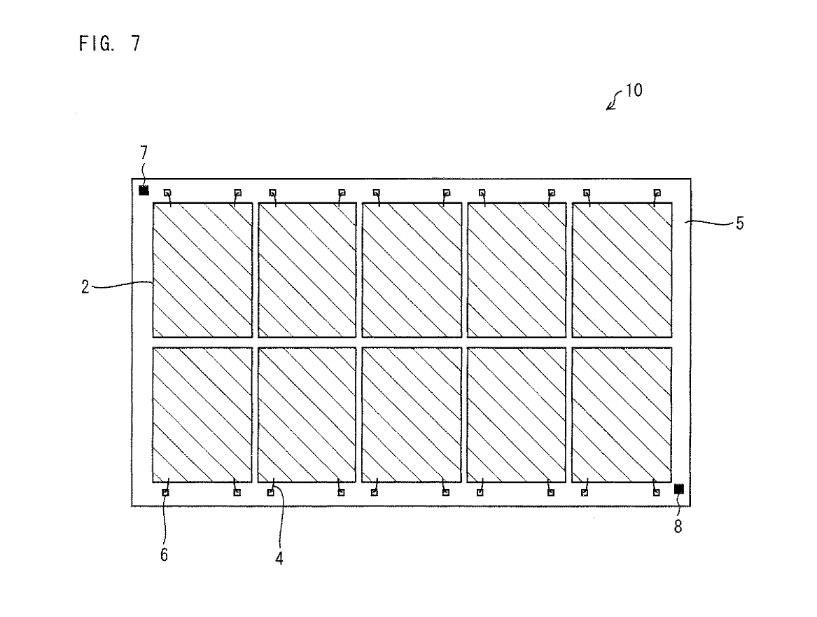

Following is an explanation of another embodiment of the present invention, with reference to FIGS. 7 to 12. It must be noted that characteristics of the present embodiment which are not explained below are identical to those of Embodiment 1. Further, for ease of explanation, members which function identically to the members indicated in the drawings for Embodiment 1 have been tagged with the same reference signs, and explanations thereof are omitted here.

FIG. 7 is a schematic view of a solar battery module 10 in accordance with the present embodiment. The solar battery module 10 is provided with ten solar battery cells 2, a cell group 3 being constituted by connecting in parallel five of the solar battery cells 2. Moreover, two cell groups 3 are connected in series. The solar battery module 10 is denominated 5-parallel, 2-series solar battery module.

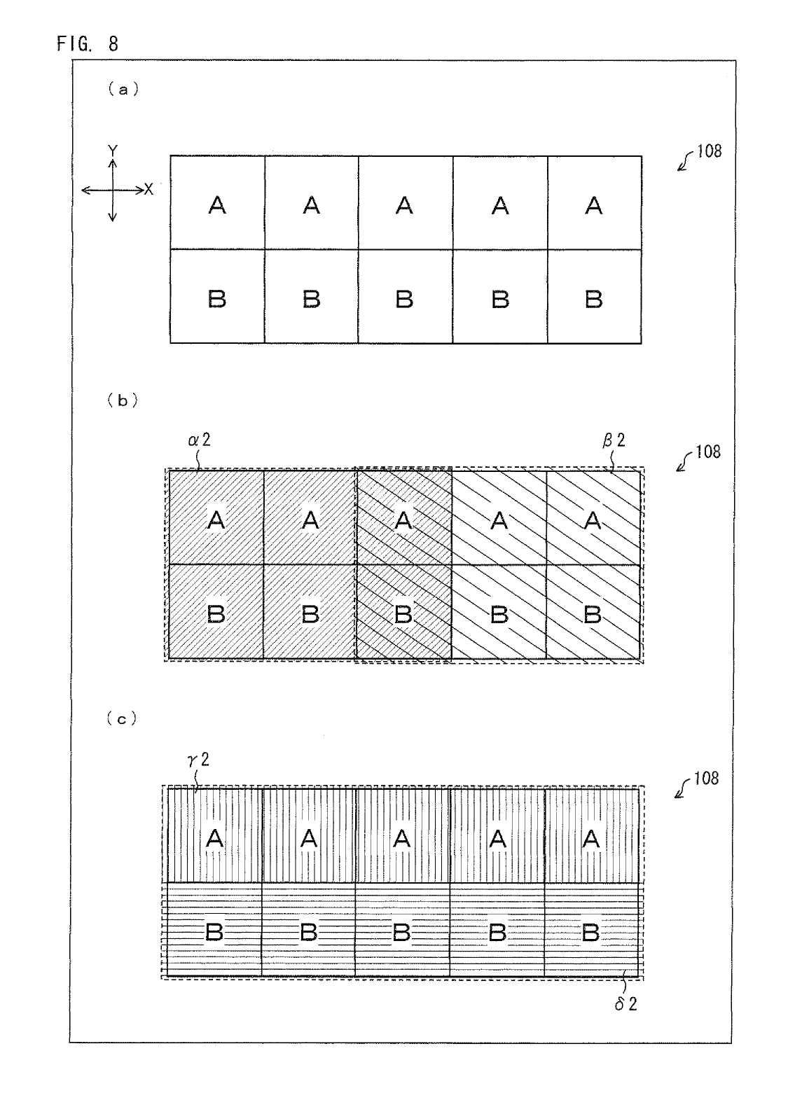

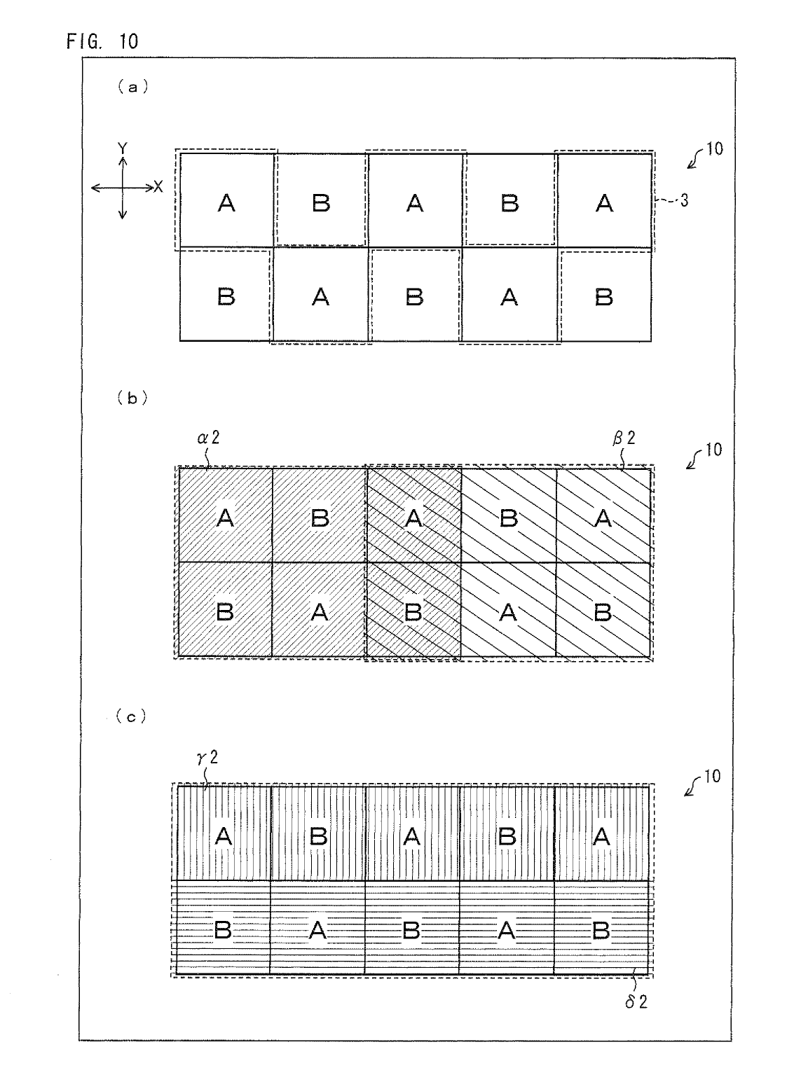

FIG. 8 is an explanatory drawing of a disposition of solar battery cells in a general solar battery module. A disposition of the solar battery cells in a conventional 5-parallel, 2-series solar battery module 108 is shown in (a) to (c) of FIG. 8. A disposition of the solar battery cells in the solar battery module 10 in accordance with the present embodiment is shown in (a) to (c) of FIG. 10.

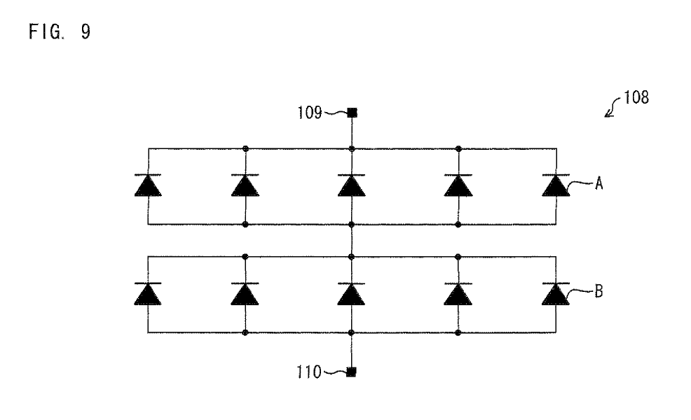

A schematic view of an internal circuit of the conventional solar battery module 108 is shown in FIG. 9. In FIG. 9, reference sign A refers to a solar battery cell A, and reference sign B refers to a solar battery cell B. In the internal circuit shown in FIG. 9, five anodes of the solar battery cells A are connected to an extraction electrode 109, and five cathodes of the solar battery cells B are connected to an extraction electrode 110. The five cathodes of the solar battery cells A and the five anodes of the solar battery cells B are connected to one another.

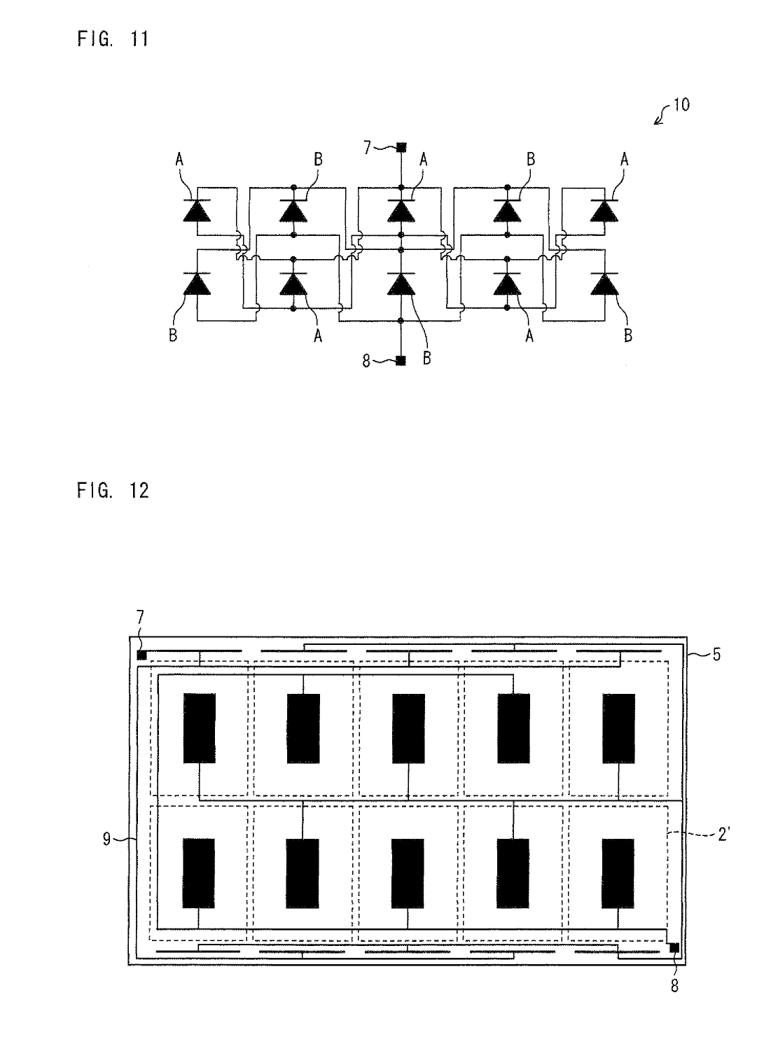

A schematic view of an internal circuit of the solar battery module 10 in accordance with the present embodiment is shown in FIG. 11 In FIG. 11, reference sign A refers to a solar battery cell A, and reference sign B refers to a solar battery cell B. In the internal circuit shown in FIG. 11, five anodes of the solar battery cells A are connected to an extraction electrode 7, and five cathodes of the solar battery cells B are connected to an extraction electrode 8. The five cathodes of the solar battery cells A and the five anodes of the solar battery cells B are connected to one another.

As shown in (b) of FIG. 8, in the conventional solar battery module 108, when a left-side ⅗ area α2 or a right-side ⅗ area β2 becomes shaded, an amount of generated electric power becomes about ⅖ of an amount of generated electric power when neither area α2 nor area β2 are shaded ((a) of FIG. 8). This is because an area receiving sunlight becomes 1−⅗=⅖. Further, as shown in (c) of FIG. 8, in the conventional solar battery module 108, when an upper ½ area γ2 or a lower ½ area δ2 becomes shaded, an amount of generated electric power becomes considerably less than ½ of an amount of generated electric power when neither area γ2 nor area δ2 are shaded.

In contrast, as shown in (b) of FIG. 10, in the solar battery module 10 in accordance with the present embodiment, when a left-side ⅗ area α2 or a right-side ⅗ area β2 becomes shaded, an amount of generated electric power becomes about ⅖ of an amount of generated electric power when neither area α2 nor area β2 are shaded ((a) of FIG. 10). Further, as shown in (c) of FIG. 10, in the solar battery module 10, when an upper ½ area γ2 or a lower ½ area δ2 becomes shaded, an amount of generated electric power becomes about ½ of an amount of generated electric power when neither area γ2 nor area δ2 are shaded, similarly to (b) of FIG. 10.

Accordingly, in the solar battery module 10 in accordance with Embodiment 2, there is no such considerable decrease of the amount of generated electric power as in the case of the conventional solar battery module 108, even when a part of the solar battery module 10 is shaded, and it is possible to achieve a stable electric power supply.

FIG. 12 illustrates an example of a pattern 9 on the module substrate 5, the pattern 9 corresponding to a disposition of the solar battery module 2 in the solar battery module 10 in accordance with the present embodiment.

Reference sign 2′ indicates where the solar battery cell 2 is disposed. Further, it is possible to simplify a routing process of the pattern 9 by forming a through-hole in the module substrate 5, and by providing at least two layers of wiring on the module substrate 5. Further, a more complex disposition of the solar battery cells becomes possible.

### Embodiment 3

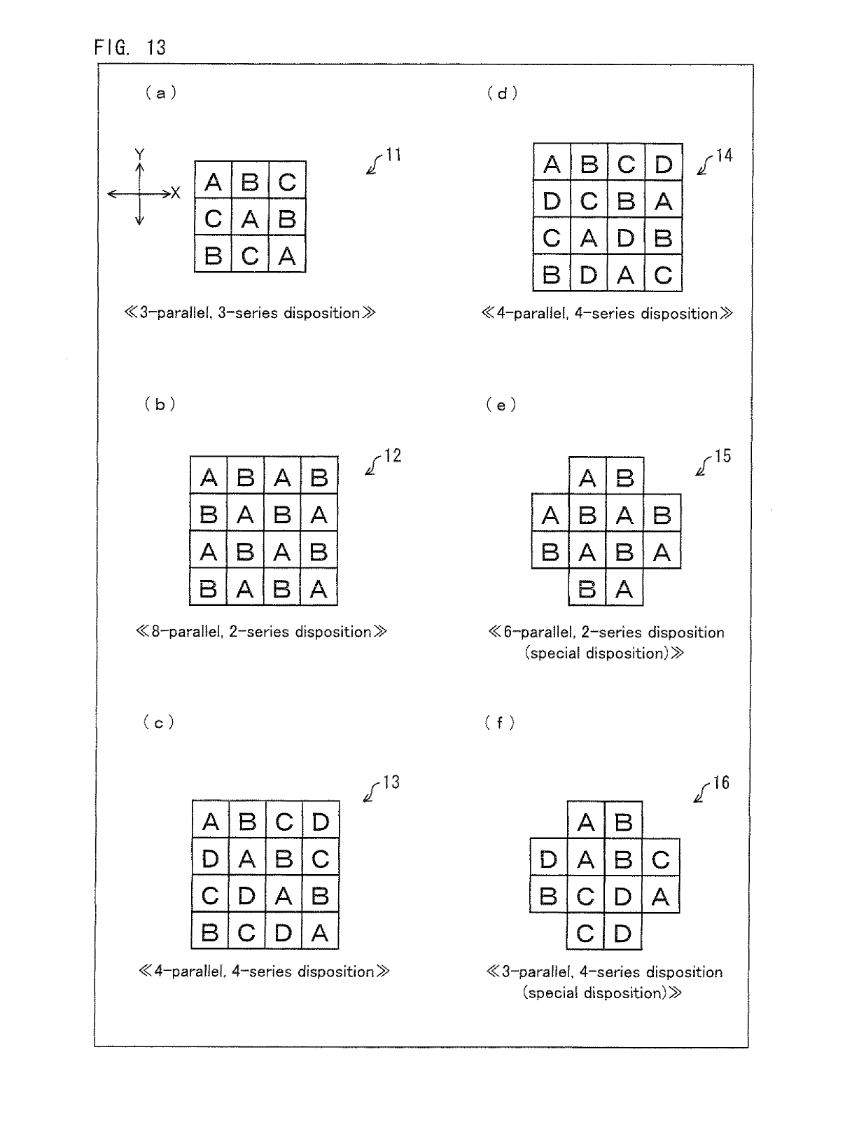

Following is an explanation of yet another embodiment of the present invention, with reference to FIG. 13. It must be noted that characteristics of the present embodiment which are not explained below are identical to those of Embodiments 1 and 2. Further, for ease of explanation, members which function identically to the members indicated in the drawings for Embodiments 1 and 2 have been tagged with the same reference sign, and explanations thereof are omitted here.

FIG. 13 is an explanatory drawing of dispositions of solar battery cells in solar battery modules 11 to 16 in accordance with the present embodiment of the present invention. (a) to (f) of FIG. 13 are schematic views of various dispositions of the solar battery cells in the solar battery modules 11 to 16 in accordance with the present embodiment of the present invention. In (a) to (f) of FIG. 13, reference signs C and D indicate solar battery cells, similarly to reference signs A and B.

With all of the above solar battery modules in accordance with the present invention, there is no such considerable decrease of the amount of generated electric power as in the case of conventional solar battery modules, even when a part of the above solar battery modules in accordance with the present invention, is shaded, and it is possible to achieve a stable electric power supply.

It must be noted that the solar battery cells A to F in accordance with Embodiments 1 to 3 constitute cell groups in each embodiment, and are independent in each embodiment. Further, in Embodiments 1 to 3, each cell group is constituted by electrically connecting in parallel at least two solar battery cells. However, as explained above regarding Embodiment 1 in (a) and (b) of FIG. 6, each cell group may also be constituted by connecting in parallel cell groups 30 (first cell group), one cell group including more than two solar battery cells electrically connected in series.

An electronic component in accordance with the present invention, an electric component in accordance with the present invention, and an electronic apparatus in accordance with the present invention are either provided with any of the above solar battery modules or supplied with electric power from any of the above solar battery modules. Accordingly, the electronic component in accordance with the present invention, the electric component in accordance with the present invention, and the electronic apparatus in accordance with the present invention make it possible to achieve a stable energy supply without a considerable decrease in electric power generation efficiency even when the solar battery module is partially shaded.

The present invention is not limited to the above-described embodiments, and various modifications are possible within the scope of the following claims. Different embodiments obtained by combining disclosed technical means as appropriate are also included within the technical scope of the present invention.

### INDUSTRIAL APPLICABILITY

The present invention makes it possible to achieve a stable energy supply without a considerable decrease in electric power generation efficiency even when partially shaded. Accordingly, the present invention can be suitably used in solar battery modules and optical electric power generating systems generating electric power from light such as sunlight and the like, as well as in electronic components, electric components and electronic apparatuses on which such solar battery modules and/or optical electric power generating systems are mounted.

### REFERENCE SIGNS LIST

1, 10, 16 solar battery module
2 solar battery cell
3 cell group (cell group, first cell group)
4 bonding wire
5 module substrate
6 on-substrate land
7, 8 extraction electrode
9 pattern
A to F solar battery cells
11 cell group (second cell group)
12 cell group (third cell group)
20 to 22 solar battery modules
30 cell group (first cell group)
31 cell group (second cell group)
32 cell group (third cell group)
α, α2, β, γ, γ2, δ, β2 areas

1. A solar battery module comprising at least two cell groups each constituted by electrically connecting in parallel at least two solar battery cells, said at least two cell groups being connected in series,
all of the solar battery cells being in a matrix disposition, each row of the matrix including at least two of said at least two cell groups; and
each column of the matrix including at least two of said at least two cell groups.

2. The solar battery module according to claim 1, wherein:
each row of the matrix includes all of said at least two cell groups; and
each column of the matrix includes all of said at least two cell groups.

3. A solar battery module comprising (i) at least two solar battery cells and (ii) at least three first cell groups each constituted by electrically connecting in parallel at least two solar battery cells,
at least two of said at least three first cell groups being electrically connected in series with each other to constitute a second cell group;
said (i) at least two solar battery cells and the second cell group are connected in parallel with each other to constitute a third cell group,
one of said at least three first cell groups not constituting the second cell group being electrically connected in series with the third cell group to constitute the solar battery module,
all of the solar battery cells being in a matrix disposition,
each row of the matrix including the first cell group and the third cell group; and
each column of the matrix including the first cell group and the third cell group.

4. The solar battery module according to claim 3, wherein:
each row of the matrix includes the first cell group, the second cell group and the third cell group; and
each column of the matrix includes the first cell group, the second cell group and the third cell group.

5. A solar battery module comprising (1) at least three solar battery cells and (ii) at least one first cell group constituted by electrically connecting in series at least two solar battery cells,
at least one of said at least three solar battery cells and said at least one first cell group being electrically connected in parallel with each other to constitute a second cell group,
at least two of said at least three solar battery cells other than the solar battery cells constituting the second cell group being electrically connected in parallel with each other to constitute a third cell group, and the third cell group and the second cell group being electrically connected in series with each other to constitute the solar battery module,
all of the solar battery cells being in a matrix disposition,
each row of the matrix including the second cell group and the third cell group, and
each column of the matrix including the second cell group and the third cell group.

6. A solar battery module comprising at least four first cell groups each constituted by electrically connecting in series at least two solar battery cells,
every at least two of said at least four first cell groups being electrically connected in parallel with each other to constitute at least two second cell groups,
said at least two second groups being electrically connected in series with each other to constitute the solar battery module,
all of the solar battery cells being in a matrix disposition,
each row of the matrix including at least two second cell groups, and
each column of the matrix including at least two second cell groups.

7. An electronic component either provided with the solar battery module according to claim 1 or supplied with electric power from the solar battery module according to claim 1.

8. An electronic component either provided with the solar battery module according to claim 3 or supplied with electric power from the solar battery module according to claim 3.

9. An electronic component either provided with the solar battery module according to claim 5 or supplied with electric power from the solar battery module according to claim 5.

10. An electronic component either provided with the solar battery module according to claim 6 or supplied with electric power from the solar battery module according to claim 6.

11. An electric component either provided with the solar battery module according to claim 1 or supplied with electric power from the solar battery module according to claim 1.

12. An electric component either provided with the solar battery module according to claim 3 or supplied with electric power from the solar battery module according to claim 3.

13. An electric component either provided with the solar battery module according to claim 5 or supplied with electric power from the solar battery module according to claim 5.

14. An electric component either provided with the solar battery module according to claim 6 or supplied with electric power from the solar battery module according to claim 6.

15. An electronic apparatus either provided with the solar battery module according to claim 1 or supplied with electric power from the solar battery module according to claim 1.

16. An electronic apparatus either provided with the solar battery module according to claim 3 or supplied with electric power from the solar battery module according to claim 3.

17. An electronic apparatus either provided with the solar battery module according to claim 5 or supplied with electric power from the solar battery module according to claim 5.

18. An electronic apparatus either provided with the solar battery module according to claim 6 or supplied with electric power from the solar battery module according to claim 6.
